(19) United States
(12) Patent Application Publication
(10) Pub. No.: US 2015/0214015 A1
(43) Pub. Date: Jul. 30, 2015

(54) FILM FORMING APPARATUS, METHOD OF FORMING LOW-PERMITTIVITY FILM, SiCO FILM, AND DAMASCENE INTERCONNECT STRUCTURE

(71) Applicants: TOKYO ELECTRON LIMITED, Tokyo (JP); TOHOKU UNIVERSITY, Miyagi (JP)

(72) Inventors: Yoshiyuki Kikuchi, Miyagi (JP); Seiji Samukawa, Miyagi (JP)

(73) Assignees: TOHOKU UNIVERSITY, Miyagi (JP); TOKYO ELECTRON LIMITED, Minato-ku, Tokyo (JP)

(21) Appl. No.: 14/422,455

(22) PCT Filed: Jun. 18, 2013
(86) PCT No.: PCT/JP2013/066731

§ 371 Date: Feb. 19, 2015

(30) Foreign Application Priority Data
Aug. 23, 2012 (JP) 2012-184298
Nov. 16, 2012 (JP) 2012-252467
May 1, 2013 (JP) 2013-096456

(51) Int. Cl. H01J 37/32; C23C 16/44; C01B 31/30; H01L 21/02; H01L 23/532; C23C 16/511; C23C 16/455

(52) U.S. Cl. CPC H01J 37/32651; C23C 16/511; C23C 16/4412; C23C 16/45557; H01J 37/3222; H01J 37/32238; H01J 37/32825; H01L 21/02274; H01L 21/02126; H01L 23/5329; C01B 31/301; H01J 2237/3321

(57) ABSTRACT

In a film forming apparatus according to an embodiment, a processing container defines a space including a plasma generation chamber and a processing chamber disposed under the plasma generation chamber. A first gas supply system supplies noble gas to the plasma generation chamber. The plasma generation chamber is sealed by a dielectric window. An antenna supplies a microwave to the plasma generation chamber via the dielectric window. A second gas supply system supplies a precursor gas to the processing chamber. A shield portion is disposed between the plasma generation chamber and the processing chamber. The shield portion includes a plurality of openings providing communication between the plasma generation chamber and the processing chamber, and has ultraviolet ray shielding property. In this film forming apparatus, the pressure in the plasma generation chamber is set greater than the pressure in the processing chamber by a factor of 4 or more.

### TECHNICAL FIELD

Exemplary embodiments of the present disclosure relate to a film forming apparatus, a method of forming a low-permittivity film, a SiCO film and a damascene structure.

### BACKGROUND ART

In a semiconductor device, a so-called damascene structure is used in which wiring is formed within an interlayer insulating film. According to high density integration and high speed operation of semiconductor devices, low-permittivity films (Low-k films) have recently been researched in order to reduce an inter-wiring capacitance.

As one method of forming such a Low-k film, a technology of irradiating neutral particle beam to a precursor gas has been suggested. In this technology, a plasma generating chamber configured to excite plasma of a rare gas and a processing chamber configured to supply a precursor gas are separated from each other, and a shielding unit is provided between the plasma generating chamber and the processing chamber, in which the shielding unit is formed with a plurality of openings configured to communicate the plasma generating chamber with the processing chamber. The shielding unit shields UV rays generated from the plasma generating chamber, and provides electrons to ions passing through the openings to neutralize the ions. In this technology, particles neutralized by the shielding unit, that is, neutral particles are irradiated to the precursor gas so that methyl is separated from a methoxy group in the molecule of the precursor gas. Accordingly, the molecules produced from the precursor gas are polymerized on a substrate to be processed (“a processing target substrate”) to form a SiCO film which is a low-permittivity film. Such a technology is disclosed in, for example, Patent Document 1. Specifically, the film formation method disclosed in Patent Document 1 excites plasma using an inductively coupled plasma source in the plasma generating chamber.

### PRIOR ART DOCUMENT

### Patent Document

Patent Document 1: Japanese Patent Laid-Open Publication No 2009-290026

### SUMMARY OF INVENTION

### Technical Problem

The inventor of the present application has conducted a research in which the technology disclosed in Patent Document 1 is applied to a processing target substrate having a larger diameter. In this research, the inventor of the present application has found that in the inductively coupled plasma source, several problems may occur due to an increase of the diameter of the processing target substrate.

For example, according to the increase of the diameter of the processing target substrate, the area of the shielding unit is increased, and the number of openings of the shielding unit is increased. As a result, the conductance of the shielding unit is increased so that the precursor gas may be easily diffused from the processing chamber to the plasma generating chamber. In order to cope with this, it is necessary to increase the pressure difference between the plasma generating chamber and the processing chamber. As a result, the pressure of the plasma generating chamber is increased. When the pressure of the plasma generating chamber is increased, plasma with a high electron temperature is generated in the inductively coupled plasma source, and neutral particles also have a high energy, so that a precursor gas may be excessively dissociated. Meanwhile, when the pressure of the plasma generating chamber is reduced, the amount of the precursor gas diffused into the plasma generating chamber is increased so that the precursor gas may be excessively dissociated. Through this phenomenon, it is estimated that a conventional technology has a limitation in achieving a low permittivity of a film.

Accordingly, what is requested in the related art are a film forming apparatus and a method of forming a low-permittivity film which are capable of forming a low-permittivity film even on a processing target substrate with a larger diameter.

### Solution to Problem

According to an aspect of the present disclosure, a film forming apparatus includes a processing container, a mounting unit, a first gas supply system, a dielectric window, an antenna, a second gas supply system, a shielding unit and an exhaust device. The processing container defines a space including a plasma generating chamber and a processing chamber below the plasma generating chamber. The mounting unit is configured to mount the processing target substrate thereon and is provided in the processing chamber. The first gas supply system is configured to supply a rare gas to the plasma generating chamber. The dielectric window is formed to seal the plasma generating chamber. The antenna is configured to supply microwaves to the plasma generating chamber through the dielectric window. In an exemplary embodiment, the antenna may be a radial line slot antenna. The second gas supply system is configured to supply a precursor gas to the processing chamber. The shielding unit is provided between the plasma generating chamber and the processing chamber, has a plurality of openings configured to communicate the plasma generating chamber with the processing chamber, and has a shielding property against UV rays. The exhaust device is connected to the processing chamber. In the film forming apparatus, a pressure of the plasma generating chamber is set to be equal to or higher than four times a pressure of the processing chamber, and a diffusion degree of the precursor gas from the processing chamber to the plasma generating chamber is set to be 0.01 or less, in which the diffusion degree is defined as an increased amount in a Pascal unit of the pressure of the plasma generating chamber when a flow rate of the precursor gas supplied to the processing chamber is increased by 1 sccm. The diffusion degree may be set by adjusting, for example, the flow rate of the precursor gas and the flow rate of the rare gas, and the exhaust amount of the exhaust device.

In the film forming apparatus, since the pressure of the plasma generating chamber is set to be equal to or higher than four times the pressure of the processing chamber, and the diffusion degree of the precursor gas from the processing chamber to the plasma generating chamber is set to be 0.01 or less, the diffusion of the precursor gas into the plasma generating chamber may be reduced. Also, in the film forming apparatus, as a plasma excitation source, microwaves are used. Unlike an inductively coupled plasma source, the microwaves may generate high-density and low-electron temperature plasma in a wide pressure range ranging from a low-pressure region to a high-pressure region. Accordingly, the particles passing through the shielding unit have an energy capable of suppressing excessive dissociation of the precursor gas. Therefore, according to the film forming apparatus, a low-permittivity film may be formed even on a processing target substrate with a larger diameter. Also, according to the film forming apparatus, a film with a low permittivity and a high refractive index, that is, a high density may be formed.

In an exemplary embodiment, the shielding unit may have a diameter of 40 cm or more. In the shielding unit having such a diameter, for example, the particles passing through the shielding unit may be relatively uniformly irradiated to a processing target substrate having a diameter of about 30 cm.

In an exemplary embodiment, the shielding unit may provide electrons to ions directed from the plasma generating chamber to the processing chamber. In this exemplary embodiment, not only the UV rays may be shielded by the shielding unit, but also the ions may be neutralized.

In an exemplary embodiment, the film forming apparatus may further include a bias power supply connected to the shielding unit. The bias power supply is configured to supply a bias power to the shielding unit so as to draw ions generated in the plasma generating chamber to the shielding unit. According to this exemplary embodiment, since the bias power is supplied to the shielding unit, a relative permittivity of the low-permittivity film may be further reduced. From this, it is estimated that when the particles passing through the shielding unit are irradiated to the precursor gas by the bias power applied to the shielding unit, a chain length of a polymer in the low-permittivity film becomes longer and the orientation of the polymer is further reduced.

In an exemplary embodiment, the first gas supply system may supply hydrogen gas to the plasma generating chamber together with the rare gas. According to this exemplary embodiment, a relative permittivity of the low-permittivity film may be further reduced, and a current leakage characteristic of the low-permittivity film may be improved. From this, it is estimated that the length of a polymer chain becomes further longer due to hydrogen supplied to the processing chamber and dangling bonds are reduced due to supply of hydrogen.

In an exemplary embodiment, the second gas supply system may supply toluene gas to the processing chamber together with the precursor gas. According to this exemplary embodiment, at least a part of the side chain of the low-permittivity film is substituted with a phenyl group. As a result, the relative permittivity and the polarizability of the low-permittivity film are further reduced.

According to another aspect of the present disclosure, there is provided a method of forming a low-permittivity film on a processing target substrate provided in a processing chamber within a processing container. The method includes: (a) generating plasma of a rare gas using microwaves in a plasma generating chamber provided above the processing chamber within the processing container; (b) supplying particles from the plasma generating chamber to the processing chamber through a shielding unit formed between the plasma generating chamber and the processing chamber, in which the shielding unit has a plurality of openings configured to communicate the plasma generating chamber with the processing chamber, and has a shielding property against UV rays; and (c) supplying a precursor gas to the processing chamber within the processing container, in which (d) a pressure of the plasma generating chamber is set to be equal to or higher than four times a pressure of the processing chamber, and a diffusion degree of the precursor gas from the processing chamber to the plasma generating chamber is set to be 0.01 or less. According to this method, a low-permittivity film may be formed even on a processing target substrate with a larger diameter. Also, according to the method, a film with a low permittivity and a high refractive index, that is, a high density may be formed.

In an exemplary embodiment, the microwaves are supplied from the radial line slot antenna. Also, in an exemplary embodiment, the shielding unit may have a diameter of 40 cm or more. Also, in an exemplary embodiment, the shielding unit may provide electrons to ions directed from the plasma generating chamber to the processing chamber.

In an exemplary embodiment, a bias power may be supplied to the shielding unit so as to draw ions generated in the plasma generating chamber to the shielding unit. According to this exemplary embodiment, a relative permittivity of the low-permittivity film may be further reduced. Also, in an exemplary embodiment, hydrogen gas may be supplied to the plasma generating chamber together with the rare gas. According to this exemplary embodiment, a relative permittivity of the low-permittivity film may be further reduced, and a current leakage characteristic of the low-permittivity film may be improved.

In an exemplary embodiment, toluene gas may be supplied to the processing chamber together with the precursor gas. According to this exemplary embodiment, the relative permittivity and the polarizability of the low-permittivity film are further reduced.

Also, according to a further aspect of the present disclosure, there is provided a SiCO film. The SiCO film has a relative permittivity less than 2.7, and a refractive index greater than 1.5. The SiCO film has a low relative permittivity, and a high refractive index, that is, a high density, and is excellent in moisture resistance. Accordingly, the SiCO film may be suitably used as a cap film in a damascene wiring structure. Also, the SiCO film may be suitably used as an interlayer insulating film in a damascene wiring structure.

Also, a SiCO film according to a still further aspect of the present disclosure is a SiCO film made of a polymer including Si atoms, O atoms, C atoms and H atoms. Assuming that, among spectrum signals obtained by analyzing the SiCO film through Fourier transform infrared spectroscopy, a total of signal areas of a signal seen near a wave number 1010 cm⁻¹, a signal seen near a wave number 1050 cm⁻¹, a signal seen near a wave number 1075 cm⁻¹, a signal seen near the wave number 1108 cm⁻¹, and a signal seen near a wave number 1140 cm⁻¹ is 100%, an area ratio of the signal seen near the wave number 1108 cm⁻¹ is 25% or more.

The signals seen near the plurality of wave numbers as described above indicate siloxane bonds having different bond angles, respectively. Among these signals, the signal seen near the wave number 1108 cm⁻¹ is a signal which indicates a siloxane bond having a bond angle of about 150°. When the area ratio of the signal seen near the wave number 1108 cm⁻¹ is 25% or more, the SiCO film includes many siloxane bonds which increase the symmetry of the linear structure. Accordingly, the SiCO film becomes a SiCO film having a low relative permittivity.

In the SiCO film in an exemplary embodiment, the area ratio of the signal seen near the wave number 1108 cm⁻¹ is 40% or more, and a full width at half maximum (“FWHM”) of the signal seen near the wave number 1108 cm⁻¹ is 35 or less. According to this exemplary embodiment, the SiCO film has a lower relative permittivity.

### Advantageous Effects of Invention

As described above, according to various aspects and exemplary embodiments of the present disclosure, there are provided an apparatus and a method for forming a low-permittivity film even on a processing target substrate with a large diameter. Also, there are provided a SiCO film with a low permittivity and a high refractive index which may be manufactured by the apparatus and the method, and a damascene structure having the SiCO film as a cap layer.

### BRIEF DESCRIPTION OF DRAWINGS

FIG. 1 is a cross-sectional view schematically illustrating a film forming apparatus according to an exemplary embodiment.

FIG. 2 is a plan view illustrating an exemplary slot plate.

FIG. 3 is a view for explaining a method of forming a low-permittivity film according to an exemplary embodiment.

FIG. 4 is a view for explaining a method of forming a low-permittivity film according to an exemplary embodiment.

FIG. 5 is a view schematically illustrating a linear structure produced by the method of forming the low-permittivity film according to an exemplary embodiment.

FIG. 6 is a view schematically illustrating a network structure and a cage structure which may be included in the low-permittivity film.

FIG. 7 is a view illustrating a semiconductor device having a damascene wiring structure according to an exemplary embodiment.

FIG. 8 is a view illustrating a relative permittivity and a refractive index of a film in Test Examples 1 to 4 and Comparative Examples 1 to 30.

FIG. 9 is a view illustrating a relationship between a pressure ratio and a diffusion degree.

FIG. 10 is a view illustrating a spectrum of a SiCO film in Test Example 6, which is obtained through Fourier transform infrared spectroscopy.

### DESCRIPTION OF EMBODIMENTS

Hereinafter, various exemplary embodiments will be described in detail with reference to drawings. Meanwhile, the same or corresponding elements in the respective drawings are given the same symbols.

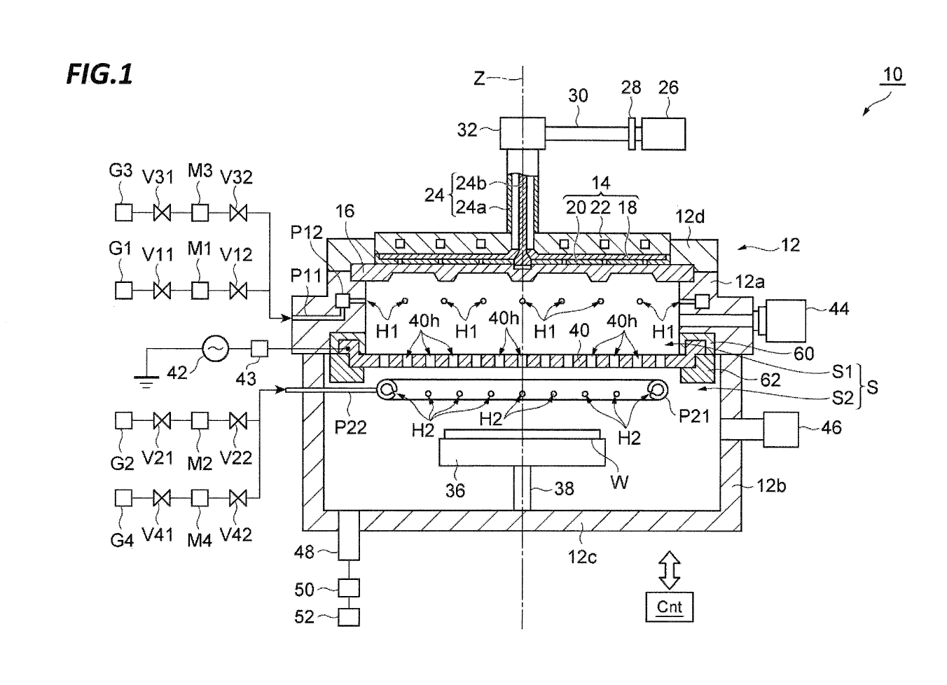

First, a film forming apparatus according to an exemplary embodiment will be described. FIG. 1 is a cross-sectional view schematically illustrating a film forming apparatus according to an exemplary embodiment. A film forming apparatus 10 illustrated in FIG. 1 includes a processing container 12. The processing container 12 is a substantially cylindrical container extending in the extension direction of the axis Z (hereinafter, referred to as “an axis Z direction”), and has a space S defined therein. The space S includes a plasma generating chamber S1 and a processing chamber S2 formed below the plasma generating chamber S1.

In an exemplary embodiment, the processing container 12 may include a first side wall 12a, a second side wall 12b, a bottom portion 12c, and a top portion 12d. These members constituting the processing container 12 are connected to a ground potential.

The first side wall 12a is formed in a substantially cylindrical shape extending in the axis Z direction, and defines the plasma generating chamber S1. Gas lines P11 and P12 are formed in the first side wall 12a. The gas line P11 extends from the outer surface of the first side wall 12a to be connected to the gas line P12. The gas line P12 extends in a substantially annular form within the first side wall 12a around the axis Z. A plurality of ejecting holes H1 is connected to the gas line P12 to eject a gas to the plasma generating chamber S1.

A gas source G1 is connected to the gas line P11 through a valve V11, a mass flow controller M1, and a valve V12. The gas source G1 is a gas source of a rare gas, and a gas source of Ar gas in an exemplary embodiment. The gas source G1, the valve V11, the mass flow controller M1, the valve V12, the gas lines P11 and P12, and the ejecting holes H1 constitute a first gas supply system according to an exemplary embodiment. The first gas supply system controls the flow rate of the rare gas from the gas source G1 by the mass flow controller M1, and supplies the rare gas at a controlled flow rate to the plasma generating chamber S1.

A gas source G3 may be connected to the gas line P11 through a valve V31, a mass flow controller M3, and a valve V32. The gas source G3 is a gas source of hydrogen gas (H₂ gas). The flow rate of the hydrogen gas from the gas source G3 is controlled by the mass flow controller M3, and the hydrogen gas is supplied to the plasma generating chamber S1 at a controlled flow rate. In this case, the gas source G3, the valve V31, the mass flow controller M3, and the valve V32, may constitute the first gas supply system together with the gas source G1, the valve V11, the mass flow controller M1, the valve V12, the gas lines P11 and P12, and the ejecting holes H1 as described above.

The top portion 12d is formed at the top of the first side wall 12a. An opening is formed in the top portion 12d, and an antenna 14 is provided within the opening. A dielectric window 16 is provided just below the antenna 14 to seal the plasma generating chamber S1.

The antenna 14 supplies microwaves to the plasma generating chamber S1 through the dielectric window 16. In an exemplary embodiment, the antenna 14 is a radial line slot antenna. The antenna 14 includes a dielectric plate 18 and a slot plate 20. The dielectric plate 18 shortens the wavelength of microwaves, and is formed substantially in a disk shape. The dielectric plate 18 is made of, for example, quartz or alumina. The dielectric plate 18 is sandwiched between the slot plate 20 and a metallic bottom surface of a cooling jacket 22. Accordingly, the antenna 14 may be constituted by the dielectric plate 18, the slot plate 20, and the bottom surface of the cooling jacket 22.

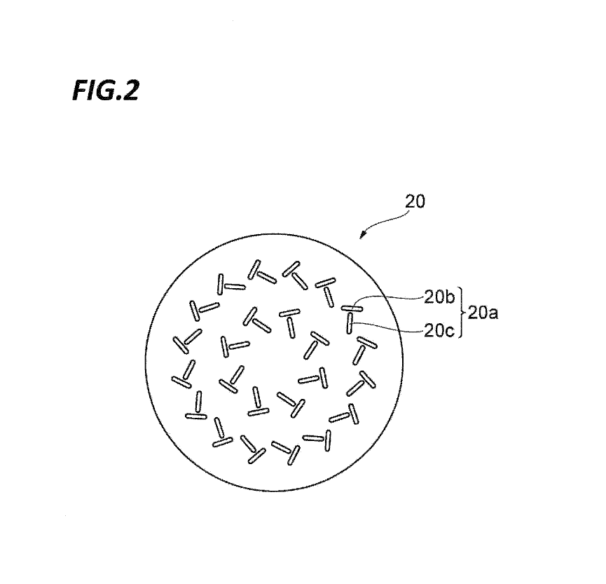

The slot plate 20 is a metallic plate formed in substantially a disk shape and is formed with a plurality of slot pairs. FIG. 2 is a plan view illustrating an example of the slot plate. A plurality of slot pairs 20a is formed in the slot plate 20. The plurality of slot pairs 20a is formed at predetermined intervals in a radial direction, and also arranged at predetermined intervals in a circumferential direction. Each of the plurality of slot pairs 20a includes two slot holes 20b and 20c. The slot holes 20b and 20c extend in intersecting or perpendicular directions.

The film forming apparatus 10 may also include a coaxial waveguide 24, a microwave generator 26, a tuner 28, a waveguide 30, and a mode converter 32. The microwave generator 26 generates microwaves having a frequency of, for example, 2.45 GHz. The microwave generator 26 is connected to the top of the coaxial waveguide 24 through the tuner 28, the waveguide 30, and the mode converter 32. The coaxial waveguide 24 extends along the axis Z as a central axis thereof. The coaxial waveguide 24 includes an outer conductor 24a and an inner conductor 24b. The outer conductor 24a is formed in a cylindrical shape extending around the axis Z. The bottom end of the outer conductor 24a may be electrically connected to the top of the cooling jacket 22 having a conductive surface. The inner conductor 24b is provided inside the outer conductor 24a. The inner conductor 24b is formed in a substantially cylindrical shape extending along the axis Z. The bottom end of the inner conductor 24b is connected to the slot plate 20 of the antenna 14.

In the film forming apparatus 10, the microwaves generated by the microwave generator 26 are propagated to the dielectric plate 18 through the coaxial waveguide 24, and provided to the dielectric window 16 from the slot holes of the slot plate 20.

The dielectric window 16 is formed in substantially a disk shape, and made of, for example, quartz or alumina. The dielectric window 16 is provided just below the slot plate 20. The dielectric window 16 transmits the microwaves received from the antenna 14 and introduces the microwaves into the plasma generating chamber S1. Accordingly, an electric field is generated just below the dielectric window 16, and plasma of the rare gas is generated within the plasma generating chamber S1. When the hydrogen gas is supplied to the plasma generating chamber S1 together with the rare gas, plasma of the hydrogen gas is also generated.

Below the first side wall 12a described above, the second side wall 12b extends to be continued to the first side wall 12a. The second side wall 12b is formed in a substantially cylindrical shape extending in the axis Z direction, and defines the processing chamber S2. The film forming apparatus 10 further includes a mounting unit 36 within the processing chamber S2. The mounting unit 36 may support a processing target substrate W on the top surface thereof. In an exemplary embodiment, the mounting unit 36 is supported by a support 38 extending in the axis Z direction from the bottom portion 12c of the processing container 12. The mounting unit 36 may include an attractively holding mechanism such as, for example, an electrostatic chuck, and a temperature control mechanism such as, for example, a refrigerant flow path connected to a chiller unit and a heater.

A pipe P21 is provided within the processing chamber S2 above the mounting unit 36 to extend annularly around the axis Z. A plurality of ejecting holes H2 is formed in the pipe P21 to eject a gas to the processing chamber S2. A pipe P22 is connected to the pipe P21 to extend to the outside of the processing container 12 through the second side wall 12b. A gas source G2 is connected to the pipe P22 through a valve V21, a mass flow controller M2, and a valve V22. The gas source G2 is a gas source of a precursor gas, and supplies a 1,3-dimethoxy tetramethyldisiloxane (DMOTMDS) gas in an exemplary embodiment. The gas source G2, the valve V21, the mass flow controller M2, the valve V22, the pipes P21 and P12, and the ejecting holes H2 constitute a second gas supply system according to an exemplary embodiment. The second gas supply system controls the flow rate of the precursor gas from the gas source G2 by the mass flow controller M2, and supplies the precursor gas at a controlled flow rate to the processing chamber S2. Meanwhile, as for the precursor gas to be supplied to the processing chamber S2 by the second gas supply system, gas species having SiO and a methyl group in a gas molecular structure (e.g., MTMOS, di-iso-propyl-dimethoxysilane, isobutyl-dimethyl-methoxysilane), gas species having a ring structure in a gas molecular structure (e.g., dimethoxy-silacyclohexane, dimethyl-silacyclohexane, 5-slaspiro[4,4]nonane), or gas species whose gas molecular structure has a structure likely to be broken by plasma, such as, for example, a benzene ring or 5-membered ring structure (e.g., dicyclopentyl-dimethoxysilane) may be used.

A gas source G4 may be connected to the gas line P22 through a valve V41, a mass flow controller M4, and a valve V42. The gas source G4 is a gas source of toluene. The flow rate of the toluene gas from the gas source G4 is controlled by the mass flow controller M4, and the toluene gas is supplied to the processing chamber S2 at the controlled flow rate. In this case, the gas source G4, the valve V41, the mass flow controller M4, and the valve V42 may constitute the second gas supply system according to an exemplary embodiment, together with the gas source G2, the valve V21, the mass flow controller M2, the valve V22, the gas lines P21 and P22, and the ejecting holes H2 as described above.

In the present film forming apparatus 10, a shielding unit 40 is provided between the plasma generating chamber S1 and the processing chamber S2. The shielding unit 40 is a member formed in substantially a disk shape, and is formed with a plurality of openings 40h which communicates the plasma generating chamber S1 with the processing chamber S2.

The shielding unit 40 is supported by, for example, the first side wall 12a. In an exemplary embodiment, the shielding unit 40 is pinched between insulating members 60 and 62, and is supported by the first side wall 12a through the insulating members 60 and 62. Accordingly, in an exemplary embodiment, the shielding unit 40 is electrically separated from the first side wall 12a. A bias power supply 42 may be connected to the shielding unit 40 to supply a bias power to the shielding unit 40. The bias power supply 42 may be a power supply for generating a high frequency bias power. In this exemplary embodiment, the bias power supply 42 supplies the high frequency bias power to shielding unit 40 in order to draw ions generated in the plasma generating chamber S1 to the shielding unit 40. In this case, a matching unit 43 having a matching circuit may be provided between the bias power supply 42 and the shielding unit 40. The matching circuit is configured to match the output impedance of the bias power supply 42 with the impedance at a load side, that is, impedance at the shielding unit 40 side. The bias power supply 42 may be a DC power supply, so that a DC bias power may be supplied to the shielding unit 40.

The shielding unit 40 has a shielding property against UV rays generated in the plasma generating chamber S1. That is, the shielding unit 40 may be made of a material that does not transmit the UV rays. Also, in an exemplary embodiment, when ions generated in the plasma generating chamber S1 are reflected by the inner wall surfaces that define the openings 40h to be transmitted through the openings 40h, the shielding unit 40 provides electrons to the ions. Accordingly, the shielding unit 40 neutralizes the ions, and releases the neutralized ions, that is, neutral particles, to the processing chamber S2. In an exemplary embodiment, the shielding unit 40 may be made of graphite. Meanwhile, in another exemplary embodiment, the shielding unit 40 may be made of an aluminum member, or made of an aluminum member whose surface is anodized or is formed with an yttria film.

Also, when the bias power is supplied to the shielding unit 40, the ions generated in the plasma generating chamber S1 are accelerated toward the shielding unit 40. As a result, the speed of the particles passing through the shielding unit 40 is increased.

In an exemplary embodiment, the shielding unit 40 has a thickness of 10 mm, and a diameter of 40 cm. The diameter of the shielding unit 40 is defined as a diameter of a surface to come in contact with the plasma generating chamber S1. Also, in an exemplary embodiment, each of the openings 40h of the shielding unit 40 has a diameter of 1 mm. Also, in an exemplary embodiment, an opening ratio of the shielding unit 40 is 10%. The opening ratio of the shielding unit 40 is defined as a ratio of the area occupied by the openings 40h with respect to the area of the surface in contact with the plasma generating chamber S1. Meanwhile, the opening ratio may range from 5% to 10%.

The film forming apparatus 10 may include the shielding unit 40 having a diameter of 40 cm or more to form a film on a processing target substrate W having a size of 8 or more inches. The shielding unit 40 having the large diameter as described above has a large conductance. Specifically, a conductance C of the shielding unit 40 is defined as follows,

C=1/4×v×A (1)

In Equation (1), v represents an average velocity of a molecule, and A is defined as follows,

A=π×1/4×D²×B (2)

In Equation (2), D represents a diameter of the shielding unit 40, and B represents an opening ratio. As clearly seen from Equations (1) and (2), when the diameter of the shielding unit 40 is increased in order to form a film on the processing target substrate W having a large diameter, the conductance of the shielding unit 40 is increased due to the square of the diameter. Accordingly, in the film forming apparatus 10, some measures need to be taken in order to suppress the precursor gas supplied to the processing chamber S2 from being diffused to the plasma generating chamber S1 through the shielding unit 40.

Accordingly, in the film forming apparatus 10, the pressure of the plasma generating chamber S1 is set to be equal to or higher than four times the pressure of the processing chamber S2, that is, the pressure ratio is set to be 4 or more, and also the diffusion degree is set to be 0.01 or less. Here, the diffusion degree is defined as an increased amount in a Pascal unit of the pressure of the plasma generating chamber S1 when the flow rate of the precursor gas supplied to the processing chamber S2 is increased by 1 sccm. The diffusion degree may be obtained from a slope of a graph indicating a relationship between a flow rate of the precursor gas and a pressure increase of the plasma generating chamber when the rare gas is supplied to the plasma generating chamber S1, and the flow rate of the precursor gas supplied to the processing chamber S2 is increased. The diffusion degree partially depends on the pressure ratio but also depends on, for example, the conductance of the shielding unit 40, the flow rate of the rare gas, and the flow rate of the precursor gas.

In an exemplary embodiment, the film forming apparatus 10 includes a pressure gauge 44 configured to measure the pressure of the plasma generating chamber S1 and a pressure gauge 46 configured to measure the pressure of the processing chamber S2. Also, in the film forming apparatus 10, a pressure regulator 50 and a vacuum pump 52 are connected to an exhaust pipe 48 connected to the processing chamber S2 at the bottom portion 12c. The pressure regulator 50 and the vacuum pump 52 constitute an exhaust device. In the film forming apparatus 10, based on the pressure measured by the pressure gauges 44 and 46, the flow rate of the rare gas may be adjusted by the mass flow controller M1, the flow rate of the precursor gas may be adjusted by the mass flow controller M2, and the exhaust amount may be adjusted by the pressure regulator 50. Accordingly, the film forming apparatus 10 may set the pressure ratio and the diffusion degree as described above.

As illustrated in FIG. 1, in an exemplary embodiment, the film forming apparatus 10 further includes a control unit Cnt. The control unit Cnt may be a control device such as, for example, a programmable computer device. The control unit Cnt is configured to control respective units of the film forming apparatus 10 according to the program based on a recipe. For example, the control unit Cnt may transmit a control signal to the valves V11 and V12 to control supply or supply interruption of the rare gas, and may transmit a control signal to the mass flow controller M1 to control the flow rate of the rare gas. Also, the control unit Cnt may transmit a control signal to the valves V31 and V32 to control supply or supply interruption of the hydrogen gas, and may transmit a control signal to the mass flow controller M3 to control the flow rate of the hydrogen gas. Also, the control unit Cnt may transmit a control signal to the valves V21 and V22 to control supply or supply interruption of the precursor gas, and may transmit a control signal to the mass flow controller M2 to control the flow rate of the precursor gas. Also, the control unit Cnt may transmit a control signal to the valves V41 and V42 to control supply or supply interruption of the toluene gas, and may transmit a control signal to the mass flow controller M4 to control the flow rate of the toluene gas. Also, the control unit Cnt may transmit a control signal to the pressure regulator 50 to control an exhaust amount. Also, the control unit Cnt may transmit a control signal to the microwave generator 26 to control the power of microwaves, and may transmit a control signal to the bias power supply 42 to control supply of a bias power into the shielding unit 40, or supply interruption of the bias power, and further a power of the bias power (e.g., an RF power).

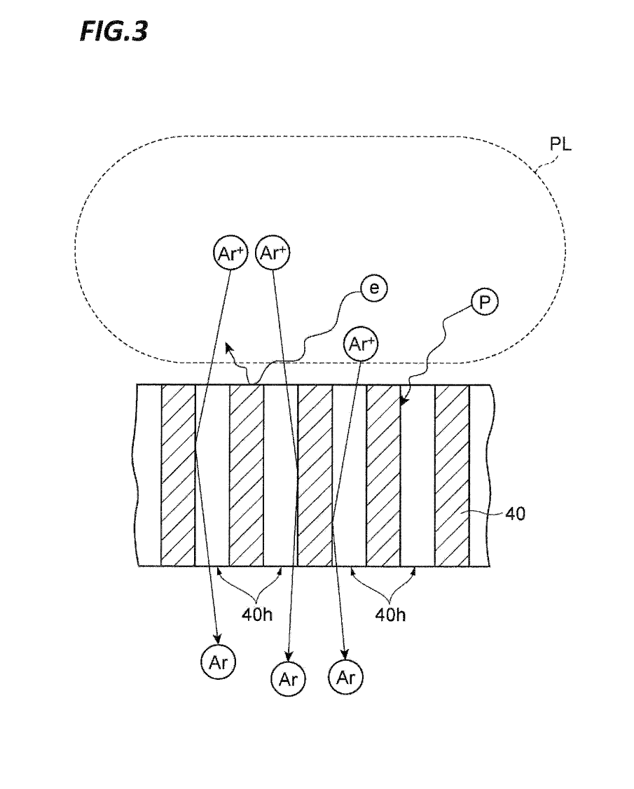

Hereinafter, a forming principle of a low-permittivity film using the film forming apparatus 10 will be described, and a method of forming the low-permittivity film according to an exemplary embodiment will be described. In this method, a rare gas is supplied to the plasma generating chamber S1 above the shielding unit 40, and microwaves are supplied to the plasma generating chamber S1. Accordingly, as illustrated in FIG. 3, plasma PL of the rare gas is generated in the plasma generating chamber S1. In FIG. 3, plasma PL of argon gas which is the rare gas is illustrated. Within the plasma PL, argon ions, electrons, and photons of UV rays are generated. In the drawing, the argon ions are indicated by circled symbol “Ar⁺”, the electrons are indicated by circled symbol “e”, and the photons are indicated by circled symbol “P”.

The electrons in the plasma PL are reflected by the shielding unit 40 to return to the plasma generating chamber S1. Also, the photons are shielded by the shielding unit 40. Meanwhile, the argon ions come in contact with the inner wall surfaces that define the openings 40h in the middle of the openings 40h of the shielding unit 40 to receive electrons from the shielding unit 40. Accordingly, the argon ions are neutralized and released to the processing chamber S2 as neutral particles. Meanwhile, in the drawing, neutral particles of argon are indicated by circled symbol “Ar”.

At the same time, a precursor gas is supplied to the processing chamber S2. Here, in the present method, the pressure ratio is set to be 4 or more, and the diffusion degree is set to be 0.01 or less so as to reduce the diffusion of the precursor gas from the processing chamber S2 to the plasma generating chamber S1. Accordingly, in the present disclosure, the amount of the precursor gas diffused to the plasma generating chamber S1 is reduced so that a phenomenon of excessive dissociation of the precursor gas is suppressed.

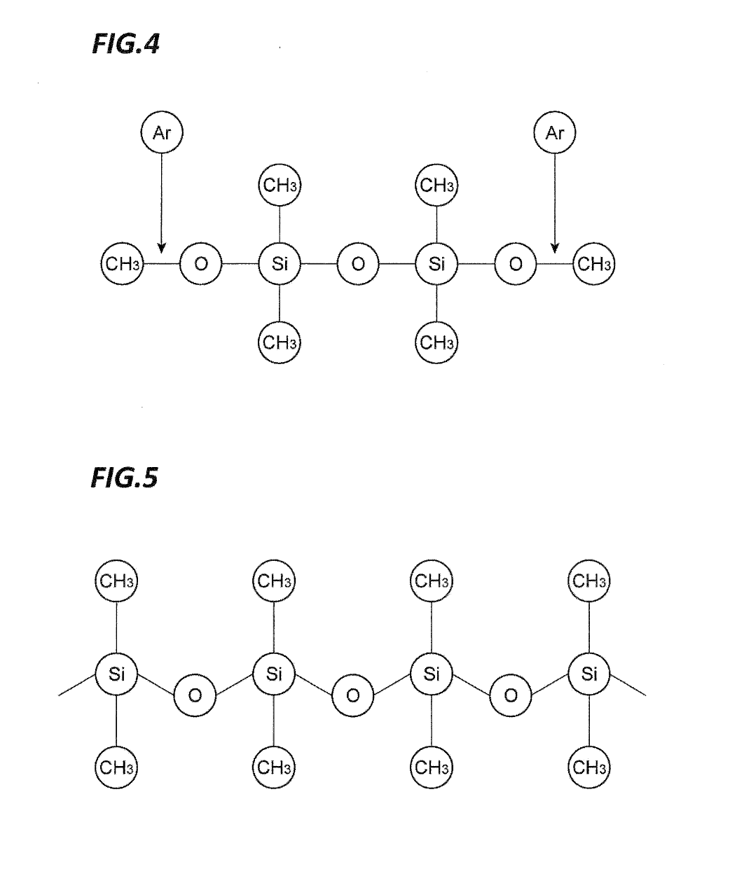

Also, as illustrated in FIG. 4, the neutral particles of argon are irradiated to a DMOTMDS gas which is the precursor gas in the processing chamber S2. As described above, in the present disclosure, the plasma of the rare gas is excited in the plasma generating chamber S1 by microwaves, that is, microwaves supplied from the radial line slot antenna in an exemplary embodiment. The microwaves, unlike an inductively coupled plasma source, may generate high-density and low-temperature plasma in a wide pressure range ranging from a low-pressure region to a high-pressure region. Accordingly, the particles passing through the shielding unit have an energy capable of suppressing excessive dissociation of the precursor gas. When such particles are irradiated to the DMOTMDS gas as the precursor gas, an O—CH₃ bond of a methoxy group is cleaved, and a methyl group bound to oxygen is removed from the DMOTMDS. Accordingly, molecules generated from the precursor gas are polymerized on the processing target substrate W so that the film having a linear structure illustrated in FIG. 5 is formed on the processing target substrate W. In the linear structure illustrated in FIG. 5, methyl groups are symmetrically bound to Si atoms. Accordingly, the linear structure has a high molecular symmetry. Also, through such a structure, an orientation polarization is cancelled, and thus the structure illustrated in FIG. 5 has a low relative permittivity k. Also, since the structures illustrated in FIG. 5 are stacked on top of each other to form a film, a high density film may be obtained. Meanwhile, the film formation using the film forming apparatus 10 may be performed by controlling the temperature of the mounting unit 36 so that the temperature of the processing target substrate W is set to 100° C. or less, for example, even to −50° C. Accordingly, the film may be formed while suppressing damage due to a temperature of devices included in the processing target substrate W.

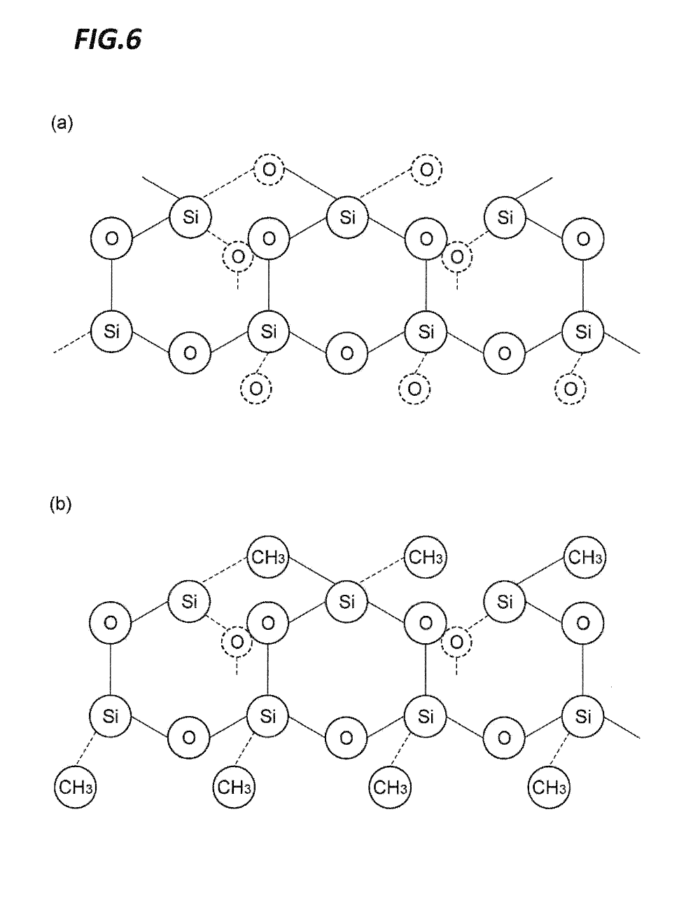

Here, in the low-permittivity film produced by a conventional PE-CVD method, the precursor gas is excessively dissociated due to a production process of the method. As a result, a film mainly composed of a cage structure illustrated in FIG. 6A is formed. That is, a film mainly composed of silicon oxide has conventionally been a porous film so as to achieve a low permittivity. Meanwhile, in the method of forming the low-permittivity film according to an exemplary embodiment, both a low permittivity and a high density of a film may be achieved. However, in the film having the structure illustrated in FIG. 5, there is no link between structures, and thus, the strength of the film may be reduced. Therefore, the process conditions may be adjusted so that the cage structure illustrated in FIG. 6A or the network structure illustrated in FIG. 6B is included as a part of a film.

In a method of forming the low-permittivity film according to another exemplary embodiment, a bias power may be supplied to the shielding unit 40. The bias power may a high frequency bias power, or a DC bias power. According to the method according to the present exemplary embodiment, a relative permittivity of a low-permittivity film is further reduced. In the method according to the present exemplary embodiment, it is estimated that the relative permittivity is further reduced due to the following reasons. That is, the particles passing through the shielding unit 40 are accelerated by the bias power applied to the shielding unit 40. When the particles accelerated by the bias power are irradiated to DMOTMDS, polymerization of molecules derived from DMOTMDS is promoted. As a result, a chain length of a polymer in the low-permittivity film becomes longer, and the orientation of the polymer is further reduced. Accordingly, it is estimated that the relative permittivity of the low-permittivity film is further reduced.

In a method of forming the low-permittivity film according to another exemplary embodiment, a bias power may be supplied to the shielding unit 40, and hydrogen gas, besides the rare gas, may be supplied to the plasma generating chamber S1. According to the method according to the present exemplary embodiment, a relative permittivity of a low-permittivity film may be further reduced, and a current leakage characteristic of the low-permittivity film may be improved. In the method according to the present exemplary embodiment, the reason the relative permittivity is further reduced and the current leakage characteristic is improved is estimated as follows. That is, when hydrogen (for example, hydrogen radicals) passing through the shielding unit 40 is irradiated to DMOTMDS, a silanol coupling polymerization is promoted so that the polymerization degree of a polymer in the low-permittivity film is further increased and the length of a polymer chain becomes further longer. Also, due to supply of hydrogen, dangling bonds of the polymer are reduced. Accordingly, it is estimated that a relative permittivity of the low-permittivity film is further decreased, and the current leakage characteristic of the low-permittivity film is improved. Meanwhile, instead of the hydrogen gas, other gases (such as, for example, water, ethanol, or methanol) capable of supplying H or OH to the precursor gas to promote the silanol coupling polymerization may be used.

In a method of forming the low-permittivity film according to another exemplary embodiment, toluene gas together with the precursor gas may be supplied to the processing chamber S2. According to the method according to the present exemplary embodiment, the side chain of the precursor gas is substituted with a phenyl group. For example, when the precursor gas is DMOTMDS, a methyl group bound to Si of MOTMDS is substituted with a phenyl group. Accordingly, the relative permittivity and the polarizability of the low-permittivity film may be further reduced.

In the foregoing, the film forming apparatus 10, and the low-permittivity film forming method which may use the film forming apparatus 10 have been described. According to the apparatus and the method, a SiCO film with a relative permittivity less than 2.7, and a refractive index greater than 1.5 may be manufactured. In an exemplary embodiment, the SiCO film is composed of a polymer including Si atoms, O atoms, C atoms, and H atoms. For example, the SiCO film includes siloxane bonds in its linear structure, and may have a structure in which methyl groups are substantially symmetrically bound to Si atoms constituting the siloxane bonds.

Also, in an exemplary embodiment, when the bias power is supplied to the shielding unit 40, a SiCO film with a relative permittivity of 2.3 or less may be manufactured. In such a SiCO film, assuming that, among spectrum signals obtained by analyzing the SiCO film through Fourier transform infrared spectroscopy, a total of signal areas of a signal seen near a wave number 1010 cm⁻¹, a signal seen near a wave number 1050 cm⁻, a signal seen near a wave number 1075 cm⁻¹, a signal seen near a wave number 1108 cm⁻¹, and a signal seen near a wave number 1140 cm⁻¹ is 100%, the area ratio of the signal seen near the wave number 1108 cm⁻¹ is 25% or more. Here, the signal area of a signal of a wave number is obtained by performing Gaussian fitting on the spectrum near the target wave number and calculating the area of the fitted Gaussian signal.

The signal seen near the wave number 1010 cm⁻¹, the signal seen near the wave number 1050 cm⁻¹, the signal seen near the wave number 1075 cm⁻¹, the signal seen near the wave number 1108 cm⁻¹, and the signal seen near the wave number 1140 cm⁻¹ are signals which indicate siloxane bonds having different bond angles, respectively. Among these signals, the signal seen near the wave number 1108 cm⁻¹ is a signal which indicates a siloxane bond having a bond angle of about 150°. Meanwhile, the bond angle may range from, for example, 147° to 154°. Such a siloxane bond increases the symmetry of the linear structure in the SiCO film to contribute to the lowering of the relative permittivity. Accordingly, when among the signals indicating siloxane bonds, the area ratio of the signal seen near the wave number 1108 cm⁻¹ is 25% or more, the SiCO film becomes a SiCO film having a low relative permittivity.

In an exemplary embodiment, when the bias power is supplied to the shielding unit 40, and the hydrogen gas is supplied to the plasma generating chamber S1 together with the rare gas, a SiCO film with a relative permittivity of 2.15 or less may be manufactured. In such a SiCO film, the area ratio of the signal seen near the wave number 1108 cm⁻¹ is 40% or more with respect to the total of the signal areas, and a FWHM of the signal seen near the wave number 1108 cm⁻¹ is 35 or less. Here, the FWHM of a signal is obtained by performing Gaussian fitting on the spectrum near a target wave number and calculating the FWHM of the fitted Gaussian signal. In such a SiCO film, siloxane bonds which increase the symmetry of the linear structure are further increased. Accordingly, the SiCO film becomes a SiCO film having a lower relative permittivity.

The SiCO film according to various exemplary embodiments, as described above, has a low relative permittivity, and a high refractive index, that is, a high density, and is excellent in moisture resistance. Accordingly, the SiCO film may be suitably used as a cap film and/or an interlayer insulating film in a damascene wiring structure.

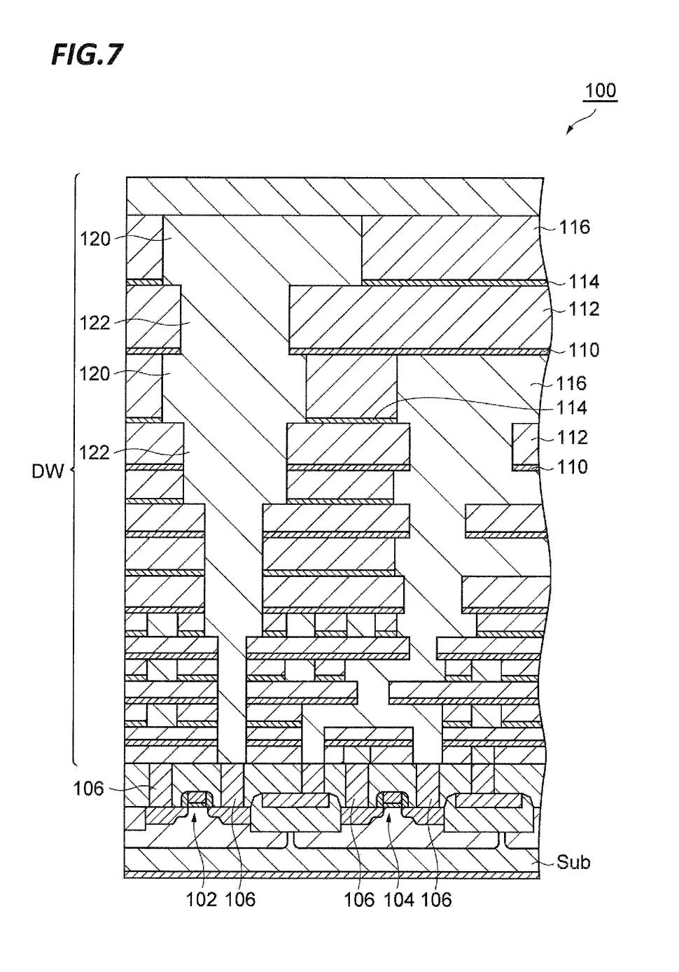

Hereinafter, a damascene wiring structure according to an exemplary embodiment will be described. FIG. 7 is a view illustrating a semiconductor device including a damascene wiring structure. A semiconductor device 100 illustrated in FIG. 7 includes devices such as, for example, MOS transistors 102 and 104 formed on a substrate Sub. Also, the semiconductor device 100 includes a damascene wiring structure DW electrically connected to the devices through a contact 106.

The damascene wiring structure DW includes a structure in which a cap layer 110, an interlayer insulating film 112, an etching stop layer 114, and an interlayer insulating film 116 are stacked in this order. A trench 120 is formed in the interlayer insulating film 116, and a wiring formed of a metallic material such as, for example, copper is formed in the trench 120. Also, a via 122 is formed in the interlayer insulating film 112 to connect a wiring formed in the interlayer insulating film 116 as an upper layer to a wiring formed in the interlayer insulating film 116 as a lower layer, and a metallic material such as, for example, copper is embedded in the via 122. As illustrated in FIG. 5, the cap layer 110 is formed on the top surface of the interlayer insulating film 116. The cap layer 110 needs to have a low relative permittivity and a moisture resistance so as to reduce an inter-wiring capacitance. As described above, according to the film forming apparatus 10, and the low-permittivity film forming method which may use the film forming apparatus 10, a SiCO film with a relative permittivity less than 2.7 may be obtained. Also, the SiCO film has a refractive index less than 1.5, that is, a high density, and thus is excellent in a moisture resistance. Accordingly, the SiCO film is suitably used as the cap layer 110. Meanwhile, the SiCO film may be used as the interlayer insulating films 112 and 116.

As described above, various exemplary embodiments have been described, but various modified exemplary embodiments may be configured without being limited thereto. For example, the precursor gas supplied to the processing chamber S2 may be OMCTS (octamethylcyclotetrasiloxane:[(CH₃)₂SiO]₄). Also, instead of the hydrogen gas, an additive gas including at least one of H₂O, CH₃OH, C₂H₅OH, TMAH (tetramethylammonium hydroxide) and NH₃ may be supplied to the plasma generating chamber S1. Meanwhile, the additive gas may be supplied to the processing chamber S2.

Hereinafter, Test Examples and Comparative Examples using the film forming apparatus 10 will be described.

### TEST EXAMPLES 1 TO 4 AND COMPARATIVE EXAMPLES 1 TO 29

First, a low-permittivity film was formed on a processing target substrate W with a diameter of 200 mm by using the film forming apparatus 10, under the conditions of Test Examples 1 to 4 and Comparative Examples 1 to 20 as noted in Table 1 below. Meanwhile, in the formation of the low-permittivity film in Test Examples 1 to 4, the temperature of the processing target substrate W was set to −50° C. Also, a low-permittivity film was formed by using another film forming apparatus which is different from the film forming apparatus 10 in which an inductively coupled plasma source is used, under the conditions of Comparative Examples 21 to 29 as noted in Table 1. In Test Examples 1 to 4 and Comparative Examples 1 to 29, as for the shielding unit 40, a shielding unit made of graphite, which has a diameter of 40 cm and a thickness of 10 mm, and openings with a diameter of 1 mm at an opening ratio of 10%, was used. Meanwhile, in Table 1, “CW” in MODE column indicates that a high frequency (RF) power was continuously supplied to a coil of an inductively coupled plasma source. Also, “TMA/B” in MODE column indicates that an RF power supplied to a coil of an inductively coupled plasma source was time-modulated, and a cycle of stopping the RF power for A sec and then supplying the RF power to the coil for B sec was repeated.

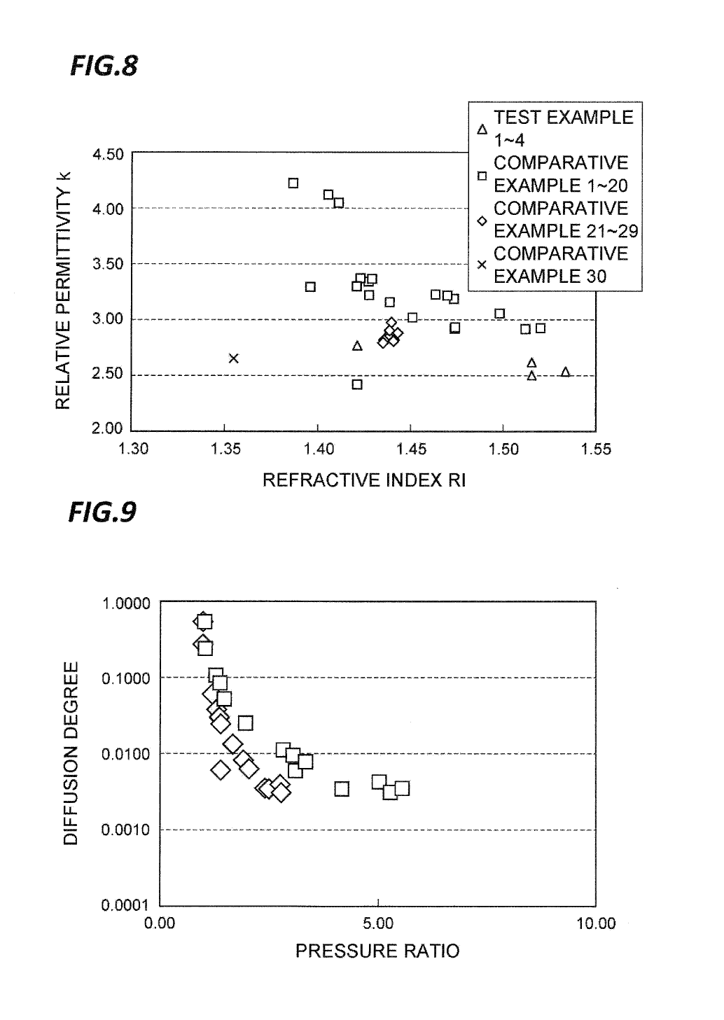

Then, a relative permittivity k of the low-permittivity film obtained from each of Test Examples and Comparative Examples was measured using a mercury probe method, and a refractive index RI was measured by an N and K method. The relative permittivity k and the refractive index RI of the low-permittivity film obtained from each of Test Examples and Comparative Examples are noted in two right columns of Table 1. Also, the relationship between the relative permittivity k and the refractive index RI of the low-permittivity film obtained from each of Test Examples and Comparative Examples is illustrated in FIG. 8. In FIG. 8, the horizontal axis represents a refractive index RI, and the vertical axis indicates a relative permittivity k. Meanwhile, in FIG. 8, a refractive index RI and a relative permittivity k of a film in Comparative Example 30 are illustrated as a reference, in which the film was made into a porous film to achieve a low permittivity.

As illustrated in Table 1 and FIG. 8, in the low-permittivity films obtained using the inductively coupled plasma source in Comparative Examples 21 to 29, the relative permittivities were not less than 2.8, and the refractive indexes were limited to 1.44. Also, the low-permittivity films in Comparative Examples 1 to 20 were formed under a condition of a pressure ratio lower than 4, in which it was impossible to compatibly achieve a relative permittivity less than 2.7 and a refractive index greater than 1.5. Meanwhile, in the low-permittivity films on processing target substrates W with a diameter of 200 mm in Test Examples 1, 3 and 4, in which the low-permittivity films were obtained using the film forming apparatus 10 under a condition of a pressure ratio of 4 or more, it was possible to compatibly achieve a relative permittivity less than 2.7 and a refractive index greater than 1.5.

TABLE 1

| | | | plasma | | | | | | | |
|---|---|---|---|---|---|---|---|---|---|---|
| | | pro- | gener- | | | | | | | |
| | | cessing | ating | | | | | | | |
| | | cham- | cham- | | micro- | | | DMOT | | |
| | | ber | ber | micro- | wave | | Ar gas | MDS | relative | refrac- |
| | pres- | pres- | pres- | wave | fre- | | flow | flow | permit- | ttive |
| | sure | sure | ure | power | quency | | rate | rate | tivity | index |
| | ratio | [Pa] | [Pa] | [W] | [GHz] | mode | [sccm] | [sccm] | k | RI |
| Test Ex. | 4.7 | 0.6 | 2.8 | 3260 | 2.45 | | 100 | 25 | 2.54 | 1.53 |
| 1 | | | | | | | | | | |
| Test Ex. | 5.4 | 1.0 | 5.4 | 3260 | 2.45 | | 100 | 25 | 2.77 | 1.42 |
| 2 | | | | | | | | | | |
| Test Ex. | 6.2 | 1.6 | 9.5 | 3260 | 2.45 | | 500 | 25 | 2.62 | 1.52 |
| 3 | | | | | | | | | | |
| Test Ex. | 6.9 | 0.3 | 2.1 | 3260 | 2.45 | | 100 | 25 | 2.50 | 1.52 |
| 4 | | | | | | | | | | |
| Comp. | 1.0 | 27.5 | 28.6 | 3260 | 2.45 | | 100 | 25 | 3.02 | 1.45 |
| Ex. 1 | | | | | | | | | | |
| Comp. | 1.0 | 27.5 | 28.6 | 1630 | 2.45 | | 100 | 25 | 3.34 | 1.43 |
| Ex. 2 | | | | | | | | | | |
| Comp. | 1.0 | 27.5 | 28.6 | 4000 | 2.45 | | 100 | 25 | 3.37 | 1.42 |
| Ex. 3 | | | | | | | | | | |
| Comp. | 1.0 | 27.5 | 28.6 | 3260 | 2.45 | | 100 | 15 | 4.12 | 1.41 |
| Ex. 4 | | | | | | | | | | |
| Comp. | 1.1 | 77.5 | 81.9 | 3260 | 2.45 | | 500 | 25 | 4.22 | 1.39 |
| Ex. 5 | | | | | | | | | | |
| Comp. | 1.1 | 19.8 | 21.0 | 3260 | 2.45 | | 100 | 25 | 3.30 | 1.42 |
| Ex. 6 | | | | | | | | | | |
| Comp. | 1.1 | 80.5 | 86.9 | 3260 | 2.45 | | 500 | 15 | 3.19 | 1.47 |
| Ex. 7 | | | | | | | | | | |
| Comp. | 1.1 | 80.5 | 86.9 | 3260 | 2.45 | | 400 | 15 | 3.22 | 1.47 |
| Ex. 8 | | | | | | | | | | |
| Comp. | 1.1 | 80.5 | 86.9 | 3260 | 2.45 | | 500 | 25 | 3.22 | 1.43 |
| Ex. 9 | | | | | | | | | | |
| Comp. | 1.1 | 80.5 | 86.9 | 3260 | 2.45 | | 500 | 20 | 3.23 | 1.46 |
| Ex. 10 | | | | | | | | | | |
| Comp. | 1.3 | 12.7 | 17.0 | 3260 | 2.45 | | 300 | 25 | 3.37 | 1.43 |
| Ex. 11 | | | | | | | | | | |
| Comp. | 1.3 | 12.7 | 17.0 | 3260 | 2.45 | | 300 | 25 | 4.05 | 1.41 |
| Ex. 12 | | | | | | | | | | |
| Comp. | 1.5 | 13.0 | 18.9 | 3260 | 2.45 | | 300 | 25 | 2.92 | 1.52 |
| Ex. 13 | | | | | | | | | | |
| Comp. | 2.3 | 1.3 | 2.9 | 3260 | 2.45 | | 100 | 25 | 3.29 | 1.40 |
| Ex. 14 | | | | | | | | | | |
| Comp. | 3.5 | 1.7 | 6.0 | 3260 | 2.45 | | 200 | 25 | 2.42 | 1.42 |
| Ex. 15 | | | | | | | | | | |
| Comp. | 3.5 | 15.0 | 55.0 | 3260 | 2.45 | | 500 | 25 | 2.92 | 1.47 |
| Ex. 16 | | | | | | | | | | |
| Comp. | 3.5 | 12.0 | 44.0 | 3260 | 2.45 | | 500 | 25 | 3.06 | 1.50 |
| Ex. 17 | | | | | | | | | | |
| Comp. | 3.5 | 3.1 | 10.9 | 3260 | 2.45 | | 500 | 25 | 3.16 | 1.44 |
| Ex. 18 | | | | | | | | | | |
| Comp. | 3.7 | 9.0 | 33.0 | 3260 | 2.45 | | 500 | 25 | 2.91 | 1.51 |
| Ex. 19 | | | | | | | | | | |
| Comp. | 3.7 | 6.0 | 22.0 | 3260 | 2.45 | | 500 | 25 | 2.93 | 1.47 |
| Ex. 20 | | | | | | | | | | |
| | | | plasma | | | | | | | |
| | | pro- | gener- | | | | | | | |
| | | cessing | ating | | | | | | | |
| | | cham- | cham- | | RF | | Ar | DMOT | | |
| | | ber | ber | | power | | gas | MDS | relative | |
| | pres- | pres- | pres- | RF | fre- | | flow | flow | permit- | refractive |
| | sure | sure | sure | power | quency | | rate | rate | tivity | index |
| | ratio | [Pa] | [Pa] | [W] | [MHz] | mode | [sccm] | [sccm] | k | RI |
| Comp. | 3.3 | 1.8 | 6.0 | 1500 | 13.56 | TM 100/200 | 250 | 25 | 2.87 | 1.44 |
| Ex. 21 | | | | | | | | | | |
| Comp. | 4.0 | 1.0 | 4.0 | 1000 | 13.56 | TM 50/200 | 300 | 25 | 2.84 | 1.44 |
| Ex. 22 | | | | | | | | | | |
| Comp. | 5.2 | 0.5 | 2.6 | 500 | 13.56 | CW | 330 | 25 | 2.82 | 1.44 |
| Ex. 23 | | | | | | | | | | |
| Comp. | 4.0 | 1.0 | 4.0 | 1000 | 13.56 | TM 100/200 | 300 | 25 | 2.88 | 1.44 |
| Ex. 24 | | | | | | | | | | |
| Comp. | 4.0 | 1.0 | 4.0 | 1500 | 13.56 | TM 50/200 | 300 | 25 | 2.97 | 1.44 |
| Ex. 25 | | | | | | | | | | |
| Comp. | 5.2 | 0.5 | 2.6 | 1500 | 13.56 | CW | 330 | 25 | 2.90 | 1.44 |
| Ex. 26 | | | | | | | | | | |
| Comp. | 5.2 | 0.7 | 3.6 | 500 | 13.56 | TM 100/200 | 330 | 25 | 2.82 | 1.44 |
| Ex. 27 | | | | | | | | | | |
| Comp. | 4.0 | 1.0 | 4.0 | 1500 | 13.56 | TM 50/200 | 300 | 25 | 2.81 | 1.44 |
| Ex. 28 | | | | | | | | | | |
| Comp. | 2.6 | 1.8 | 4.7 | 1000 | 13.56 | CW | 250 | 25 | 2.79 | 1.44 |
| Ex. 29 | | | | | | | | | | |

Also, in the low-permittivity films in Test Example 1, and Comparative Examples 3, 15, and 30, concentrations of Si (silicon), C (carbon) and O (oxygen) were measured by XPS (X-ray photoelectron spectroscopy), and the densities of the low-permittivity films were obtained by XRR (X-ray reflectivity method). The results are noted in Table 2.

TABLE 2

| | Si | C | O | C/Si | O/Si | |
|---|---|---|---|---|---|---|
| | concentration | concentration | concentration | concentration | concentration | Density |
| | [atm %] | [atm %] | [atm %] | ratio | ratio | (g/cm³) |
| Test Ex. 1 | 15.31 | 60.41 | 24.29 | 3.9 | 1.6 | 2.22 |
| Comp. | 18.96 | 54.74 | 26.3 | 2.9 | 1.4 | 1.75 |
| Ex. 3 | | | | | | |
| Comp. | 20.8 | 52.95 | 26.97 | 2.5 | 1.3 | 1.9 |
| Ex. 15 | | | | | | |
| Comp. | 24.9 | 19 | 55.8 | 0.8 | 2.2 | 1.35 |
| Ex. 30 | | | | | | |

As noted in Table 2, it was found that the low-permittivity film in Test Example 1 has a higher carbon concentration than those of the low-permittivity films in Comparative Examples 3, 15 and 30, and under the process condition of Test Example 1, methyl groups were not excessively separated from DMOTMDS. Also, from the concentration ratio of C and Si, and the concentration ratio of O and Si in the low-permittivity film as noted in Table 2, it is estimated that the film mainly including the linear structure as illustrated in FIG. 5 was formed in Test Example 1. Also, it was found that the density of the low-permittivity film in Test Example 1 is much larger than the density of the low-permittivity film of each of Comparative Examples 3, 15 and 30.

Then, the relationship between a pressure ratio and a diffusion degree was obtained by changing the pressure ratio of the film forming apparatus 10. In this experiment as well, as for the shielding unit 40, a shielding unit made of graphite, which has a diameter of 40 cm and a thickness of 10 mm, and openings with a diameter of 1 mm at an opening ratio of 10%, was used. The relationship between the pressure ratio and the diffusion degree obtained from the present experiment is illustrated in FIG. 9. As illustrated in FIG. 9, in the film forming apparatus 10, when the pressure ratio was 4 or more, the diffusion degree was 0.01 or less. However, in some cases, even when the pressure ratio was about 2, the diffusion degree was 0.01 or less. Accordingly, it was found that in the film forming apparatus 10, it is required to set the diffusion degree to 0.01 or less, and to set the pressure ratio to 4 or more in order to form a film having a low relative permittivity and a high refractive index on a large-diameter processing target substrate W.

### TEST EXAMPLES 5 AND 6 AND COMPARATIVE EXAMPLES 31 AND 32

In Test Examples 5 and 6 and Comparative Examples 31 and 32, low-permittivity films were formed on processing target substrates W with a diameter of 200 mm under the conditions noted in Table 3 below. Meanwhile, in the formation of the low-permittivity films in Test Examples 5 and 6, the temperature of the processing target substrates W was set to −50° C. More specifically, in Test Example 5, Ar gas was only supplied to the plasma generating chamber S1 and a high frequency bias power was supplied to the shielding unit 40, using the film forming apparatus 10. Also, in Test Example 6, Ar gas and H₂ gas were supplied to the plasma generating chamber S1 and a high frequency bias power was supplied to the shielding unit 40, using the film forming apparatus 10. Also, in Comparative Example 31, Ar gas and O₂ gas were supplied to the plasma generating chamber S1 and a high frequency bias power was supplied to the shielding unit 40, using the film forming apparatus 10. Also, in Comparative Example 32, Ar gas and MTMOS (methyltrimethoxysilane) gas were supplied to the plasma generating chamber S1 and a high frequency bias power was supplied to the shielding unit 40, using the film forming apparatus 10. Meanwhile, in Test Examples 5 and 6 and Comparative Examples 31 and 32, a shielding unit made of graphite was used as the shielding unit 40 in which the shielding unit had a diameter of 40 cm and a thickness of 10 mm and included openings with a diameter of 1 mm at an opening ratio of 10%.

TABLE 3

| | | | plasma | | | | | Ar | | |
|---|---|---|---|---|---|---|---|---|---|---|
| | | processing | generating | | | | bias | gas | | |
| | | chamber | chamber | | microwave | bias | power | flow | H₂ gas | DMOTMDS |
| | pressure | pressure | pressure | microwave | frequency | power | frequency | rate | flow rate | flow rate |
| | ratio | [Pa] | [Pa] | power [W] | [GH] | (W) | (kHz) | [sccm] | [sccm] | [sccm] |
| Test | 7.7 | 0.3 | 2.3 | 3260 | 2.45 | 150 | 150 | 100 | | 25 |
| Example 5 | | | | | | | | | | |
| Test | 7.7 | 0.3 | 2.3 | 3260 | 2.45 | 150 | 150 | 90 | 10 | 25 |
| Example 6 | | | | | | | | | | |
| | | | plasma | | | | | Ar | | |
| | | processing | generating | | | | bias | gas | | |
| | | chamber | chamber | | microwave | bias | power | flow | O₂ gas | DMOTMDS |
| | pressure | pressure | pressure | microwave | frequency | power | frequency | rate | flow rate | flow rate |
| | ratio | [Pa] | [Pa] | power [W] | [GH] | (W) | (kHz) | [sccm] | [sccm] | [sccm] |
| Comparative | 7.7 | 0.3 | 2.3 | 3260 | 2.45 | 150 | 150 | 95 | 5 | 25 |
| Example 31 | | | | | | | | | | |
| | | | plasma | | | | | Ar | | |
| | | processing | generating | | | | bias | gas | MTMOS | |
| | | chamber | chamber | | microwave | bias | power | flow | gas | DMOTMDS |
| | pressure | pressure | pressure | microwave | frequency | power | frequency | rate | flow rate | flow rate |
| | ratio | [Pa] | [Pa] | power [W] | [GH] | (W) | (kHz) | [sccm] | [sccm] | [sccm] |
| Comparative | 7.7 | 0.3 | 2.3 | 3260 | 2.45 | 150 | 150 | 95 | 5 | 25 |
| Example 32 | | | | | | | | | | |

Then, a deposition rate, a relative permittivity and a leakage current of the low-permittivity film obtained from each of Test Examples and Comparative Examples were measured. The results are noted in Table 4 below.

TABLE 4

| | deposition rate | relative | leakage current |
|---|---|---|---|
| | (nm/min) | permittivity | (A/cm²) |
| Example 5 | 0.6 | 2.3 | 1 × 10⁻⁷ |
| Example 6 | 0.8 | 2.15 | <1 × 10⁻⁸ |
| Comp. Ex. 31 | 1.4 | 3.6 | 5 × 10⁻⁸ |
| Comp. Ex. 32 | 0.6 | 3.34 | 1 × 10⁻⁷ |

As noted in Table 4, in Test Example 5, it was found that when the bias power is supplied to the shielding unit 40, the relative permittivity of the low-permittivity film may be reduced to a small value, specifically 2.3. Also, in Test Example 6, it was found that when Ar gas and H₂ gas are supplied to the plasma generating chamber besides the supply of bias power to the shielding unit 40, it is possible to form a low-permittivity film which has a lower relative permittivity and a lower leakage current than the low-permittivity film obtained in Test Example 5. Meanwhile, in each of Comparative Examples 31 and 32, it was found that when O₂ gas or MTMOS gas is supplied to the plasma generating chamber S1, instead of H₂ gas in addition to Ar gas, the relative permittivity of the formed low-permittivity film is higher than the relative permittivity of the low-permittivity film of Test Example 5.

Also, the low-permittivity films obtained in Test Examples 1, 5 and 6 were heated from room temperature to 400° C. at a temperature rising speed of 10° C. per minute in vacuum, and reduction rates of film thicknesses through the heating of the low-permittivity films were measured. As a result of the measurement, the film thickness reduction rates of the low-permittivity films in Test Examples 1, 5 and 6 were 23%, 32%, and 5%, respectively. Therefore, it was found that when the bias power is supplied to the shielding unit 40 and Ar gas and H₂ gas are supplied to the plasma generating chamber, the heat resistance of the low-permittivity film is improved, that is, the polymerizability is increased.

### TEST EXAMPLE 7

In Test Example 7, toluene gas was supplied to the processing chamber S2 at a flow rate of 30 sccm and low-permittivity films were formed on ten processing target substrates W with a diameter of 200 mm. Meanwhile, in the formation of the low-permittivity films in Test Example 7, the temperature of the processing target substrates W was set to −50° C. Other conditions of Test Example 7 were the same as those in Test Example 5.

Then, an average of relative permittivity values and an average of polarizability values of the low-permittivity films which were formed on ten processing target substrates W through the processings in Test Example 7 were obtained. The average of relative permittivity values and the average of polarizability values of the low-permittivity films formed on the ten processing target substrates W through the processings in Test Example 7 were 2.24 and 0.2, respectively. Also, the polarizabilities of the low-permittivity films formed through the processings in Test Examples 1 to 4 and Comparative Examples 1 to 29 were also calculated. Here, the polarizability may be calculated by square of (relative permittivity-refractive index). When the polarizabilities of the low-permittivity films formed through processings in Test Examples 1 to 4 and Comparative Examples 1 to 29 were calculated based on the calculation equation of the polarizability, a low-permittivity film having the smallest polarizability among the low-permittivity films was the low-permittivity film formed through processings in Test Example 4, and its polarizability was about 1.0. Therefore, it was found that when the toluene gas is supplied to the processing chamber S2 together with the precursor gas, the relative permittivity and the polarizability of the low-permittivity film may be further reduced.

(Evaluation of Low-Permittivity Film in Test Examples 4 to 6 through Fourier Transform Infrared Spectroscopy)

The low-permittivity films obtained in Test Examples 4 to 6, that is, SiCO films, were analyzed through Fourier transform infrared spectroscopy. Then, in each Test Example, respective areas of a signal seen near a wave number 1010 cm⁻¹, a signal seen near a wave number 1050 cm⁻¹, a signal seen near a wave number 1075 cm⁻¹, a signal seen near a wave number 1108 cm⁻¹ and a signal seen near a wave number 1140 cm⁻¹ were obtained. When a total of the signal areas was 100%, the area ratio (%) of the signal seen near the wave number 1108 cm⁻¹ was obtained from the spectrums obtained through Fourier transform infrared spectroscopy. Meanwhile, the signal areas were obtained by performing Gaussian fitting on the spectrums near the target wave numbers and calculating the areas of the fitted Gaussian signals.

Also, in each of SiCO films of Test Examples 4 to 6, from the spectrum obtained through Fourier transform infrared spectroscopy, a FWHM of the signal seen near the wave number 1108 cm⁻¹ was obtained. The FWHMs of the signals were obtained by performing Gaussian fitting on the spectrums near the target wave numbers and calculating the FWHMs of the fitted Gaussian signals.

In each of the low-permittivity films of Test Examples 4 to 6, area ratios of signals seen near the wave number 1010 cm⁻¹, signals seen near the wave number 1050 cm⁻¹, signals seen near the wave number 1075 cm⁻¹, signals seen near the wave number 1108 cm⁻¹ and signals seen near the wave number 1140 cm⁻¹ are noted in Table 5. Also, in each of the low-permittivity films of Test Examples 4 to 6, the FWHMs of the signals seen near the wave number 1108 cm⁻¹ are noted in Table 6.

TABLE 5

| | relative | wave number (cm⁻¹) | | | | |
|---|---|---|---|---|---|---|
| | permittivity | 1010 | 1050 | 1075 | 1108 | 1140 |
| Test Ex. 4 | 2.5 | 14.0% | 0.0% | 51.1% | 4.0% | 30.9% |
| Test Ex. 5 | 2.3 | 0.0% | 34.9% | 0.0% | 25.1% | 39.9% |
| Test Ex. 6 | 2.15 | 0.0% | 44.1% | 1.8% | 40.9% | 13.2% |

TABLE 6

| | relative | FWHM of signals of wave |
|---|---|---|
| | permittivity | number 1108 (cm⁻¹) |
| Test Ex. 4 | 2.5 | 40 |
| Test Ex. 5 | 2.3 | 60 |
| Test Ex. 6 | 2.15 | 35 |

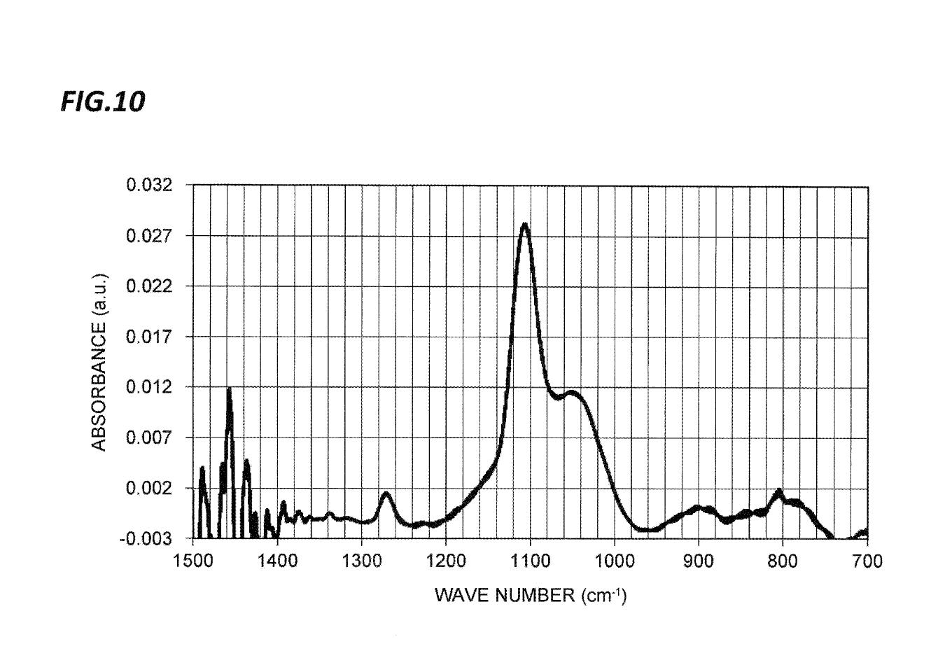

As illustrated in Table 5, it was found that in the SiCO films of Test Examples 5 and 6, the area ratios of signals seen near the wave number 1108 cm⁻¹ were about 25% or more, and many siloxane bonds which increase the symmetry of the linear structure were included. Also, in the SiCO film of Test Example 6, it was found that the area ratio of the signal seen near the wave number 1108 cm⁻¹ was about 40% or more, and more siloxane bonds which increase the symmetry of the linear structure were included. Here, the spectrum of the SiCO film of Test Example 6, which was obtained through Fourier transform infrared spectroscopy, is illustrated in FIG. 10. As illustrated in FIG. 10, in the SiCO film of Test Example 6, the signal seen near the wave number 1108 cm⁻¹ has a sharp peak, and as noted in Tables 5 and 6, the FWHM of the signal seen near the wave number 1108 cm⁻¹ was 35 or less. Therefore, it was found that the SiCO film of Test Example 6 includes more siloxane bonds which increase the symmetry of the linear structure and have a small variation in a bond angle.

### DESCRIPTION OF SYMBOLS

10: film forming apparatus, 12: processing container, 14: antenna, 16: dielectric window, 18: dielectric plate, 20: slot plate, 22: cooling jacket, 24: coaxial waveguide, 26: microwave generator, 28: tuner, 30: waveguide, 32: mode converter, 36: mounting unit, 40: shielding unit, 40h: opening, 42: bias power supply, 44, 46: pressure gauge, 48: exhaust pipe, 50: pressure regulator, 52: vacuum pump, G1: gas source (rare gas), H1: ejecting hole, M1: mass flow controller, V11, V12: valve, G2: gas source (precursor gas), H2: ejecting hole, M2: mass flow controller, V21, V22: valve, Cnt: control unit, 100: semiconductor device, DW: damascene wiring structure, 102: transistor, 110: cap layer, 112: interlayer insulating film, 114: etching stop layer, 116: interlayer insulating film, 120: trench, 122: via

1. A film forming apparatus comprising:
a processing container which defines a space including a plasma generating chamber and a processing chamber below the plasma generating chamber;
a mounting unit provided in the processing chamber;
a first gas supply system configured to supply a rare gas to the plasma generating chamber;
a dielectric window provided to seal the plasma generating chamber;
an antenna configured to supply microwaves to the plasma generating chamber through the dielectric window;
a second gas supply system configured to supply a precursor gas to the processing chamber;
a shielding unit provided between the plasma generating chamber and the processing chamber, in which the shielding unit has a plurality of openings configured to communicate the plasma generating chamber with the processing chamber, and has a shielding property against UV rays; and
an exhaust device connected to the processing chamber,
wherein a pressure of the plasma generating chamber is set to be equal to or higher than four times a pressure of the processing chamber, and a diffusion degree of the precursor gas from the processing chamber to the plasma generating chamber is set to be 0.01 or less, in which the diffusion degree is defined as an increased amount in a Pascal unit of the pressure of the plasma generating chamber when a flow rate of the precursor gas supplied to the processing chamber is increased by 1 sccm, and
the first gas supply system is configured to supply hydrogen gas to the plasma generating chamber together with the rare gas.

2. The film forming apparatus of claim 1, further comprising a bias power supply connected to the shielding unit, wherein the bias power supply is configured to supply a bias power to the shielding unit so as to draw ions generated in the plasma generating chamber to the shielding unit.

3. (canceled)

4. The film forming apparatus of claim 1, wherein the second gas supply system is configured to supply toluene gas to the processing chamber together with the precursor gas.

5. The film forming apparatus of claim 1, wherein the antenna is a radial line slot antenna.

6. The film forming apparatus of claim 1, wherein the shielding unit has a diameter of 40 cm or more.

7. The film forming apparatus of claim 1, wherein the shielding unit provides electrons to ions directed from the plasma generating chamber to the processing chamber.

8. A method of forming a low-permittivity film on a processing target substrate provided in a processing chamber within a processing container, the method comprising:
generating plasma of a rare gas using microwaves in a plasma generating chamber provided above the processing chamber within the processing container;
supplying particles from the plasma generating chamber to the processing chamber through a shielding unit formed between the plasma generating chamber and the processing chamber, in which the shielding unit has a plurality of openings configured to communicate the plasma generating chamber with the processing chamber, and has a shielding property against UV rays; and
supplying a precursor gas to the processing chamber,
wherein a pressure of the plasma generating chamber is set to be equal to or higher than four times a pressure of the processing chamber, and a diffusion degree of the precursor gas from the processing chamber to the plasma generating chamber is set to be 0.01 or less, in which the diffusion degree is defined as an increased amount in a Pascal unit of the pressure of the plasma generating chamber when a flow rate of the precursor gas supplied to the processing chamber is increased by 1 sccm.

9. The method of claim 8, wherein a bias power is supplied to the shielding unit so as to draw ions generated in the plasma generating chamber to the shielding unit.

10. The method of claim 9, wherein hydrogen gas together with the rare gas is supplied to the plasma generating chamber.

11. The method of claim 8, wherein toluene gas together with the precursor gas is supplied to the processing chamber.

12. The method of claim 8, wherein the microwaves are supplied from a radial line slot antenna.

13. The method of claim 8, wherein the shielding unit has a diameter of 40 cm or more.

14. The method of claim 8, wherein the shielding unit provides electrons to ions directed from the plasma generating chamber to the processing chamber.

15. A SiCO film having a relative permittivity less than 2.7, and a refractive index greater than 1.5.

16. A damascene wiring structure having the SiCO film of claim 15 as a cap layer.

17. A SiCO film made of a polymer including Si atoms, O atoms, C atoms and H atoms, wherein assuming that a total of signal areas of a signal seen near a wave number 1010 cm⁻¹, a signal seen near a wave number 1050 cm⁻¹, a signal seen near a wave number 1075 cm⁻¹, a signal seen near the wave number 1108 cm⁻¹, and a signal seen near a wave number 1140 cm⁻¹ is 100% among spectrum signals obtained by analyzing the SiCO film through Fourier transform infrared spectroscopy, an area ratio of a signal seen near the wave number 1108 cm⁻¹ is 25% or more.

18. The SiCO film of claim 17, wherein the area ratio of the signal seen near the wave number 1108 cm⁻¹ is 40% or more, and a full width at half maximum of the signal seen near the wave number 1108 cm⁻¹ is 35 or less.
